(19) United States
(12) Patent Application Publication
(10) Pub. No.: US 2023/0402337 A1
(43) Pub. Date: Dec. 14, 2023

(54) 3D INTERPOSER WITH THROUGH GLASS VIAS - METHOD OF INCREASING ADHESION BETWEEN COPPER AND GLASS SURFACES AND ARTICLES THEREFROM

(71) Applicant: CORNING INCORPORATED, CORNING, NY (US)

(72) Inventors: Jin Su Kim, Seoul (KR); Daniel Wayne Levesque, Jr., Avoca, NY (US); Aize Li, Painted Post, NY (US); Heather Nicole Vanselous, Corning, NY (US)

(21) Appl. No.: 18/035,343

(22) PCT Filed: Nov. 9, 2021
(86) PCT No.: PCT/US2021/058613

§ 371 Date: May 4, 2023

Related U.S. Application Data
(60) Provisional application No. 63/114,122, filed on Nov. 16, 2020.

(51) Int. Cl. H01L 23/15; H01L 23/13; H01L 21/48; B32B 17/06; B32B 3/26; C03C 15/00

(52) U.S. Cl. CPC H01L 23/15; H01L 23/13; H01L 21/481; B32B 17/06; B32B 3/266; C03C 15/00; B32B 2250/40

(57) ABSTRACT

In some embodiments, a method comprises forming a pilot hole or damage track through a laminate glass structure using a laser. The laminate glass structure comprising a first layer and a second layer adjacent to the first layer. The first layer is formed from a first glass composition. The second layer is formed from a second glass composition different from the first glass composition. After forming the pilot hole, the laminate glass structure is exposed to etching conditions that etch the first glass composition at a first etching rate and the second glass composition at a second etching rate, wherein the first etch rate is different from the second etch rate, to form an etched hole.

### CROSS-REFERENCE TO RELATED APPLICATIONS

This application claims the benefit of priority under 35 U.S.C. § 119 of U.S. Provisional Ser. No. 63/114,122 filed on Nov. 16, 2020, the content of which is relied upon and incorporated herein by reference in its entirety.

### FIELD

This description pertains to glass surfaces and articles having through vias with new geometries and/or improved adhesion to copper.

### BACKGROUND

3D interposers with through package via (TPV) interconnects that connect the logic device on one side and memory on the other side is an important technology for high bandwidth devices. Glass and glass ceramic substrates with vias are desirable for many applications, including for use as in interposers used as an electrical interface, RF filters, and RF switches. The current substrates of choice are polymer or silicon. Polymer interposers suffer from poor dimensional stability while silicon wafers are expensive and suffer from high dielectric loss due to semiconducting properties. There is a trend, therefore, toward use of glass as a superior substrate material due to its low dielectric constant, thermal stability, and low cost. Current challenges to make glass through vias are long process times and limited aspect ratio of vias. Glass through vias can be fully or conformally filled by conducting metals such as copper to provide an electrical pathway. The chemical inertness and low intrinsic roughness of glass, however, pose a problem related to adhesion of the copper with the glass wall inside the vias. Lack of adhesion between copper and glass could lead to reliability issues such as cracking, delamination and low pull-out strength.

Accordingly, a need exists for a TGV structure with a conducting metal that has improved reliability. A need also exists for manufacturing glass substrates with through vias in an efficient manner with a higher degree of control of via geometry and aspect ratios.

### SUMMARY

Corning has developed through glass vias (TGV) processing technology to create either through or blind vias in glass substrates. This technology can produce TGV in laminate glasses composed of fast-etching clad and slow-etching core and laminate glasses composed of slow-etching clad and fast-etching core. The present disclosure provides methods of making glass through vias from laminate glass substrate in a shortened time compared to single glass compositions, wherein the glass vias have unique and improved shapes. The present disclosure provides methods of making glass through vias that have geometries that keep metal filling secure within the through vias.

In a 1st aspect, a method comprises forming a pilot hole or damage track through a laminate glass structure using a laser. The laminate glass structure comprising a first layer and a second layer adjacent to the first layer. The first layer is formed from a first glass composition. The second layer is formed from a second glass composition different from the first glass composition. After forming the pilot hole, the laminate glass structure is exposed to etching conditions that etch the first glass composition at a first etching rate and the second glass composition at a second etching rate, wherein the first etch rate is different from the second etch rate, to form an etched hole.

In a 2^{nd} aspect, for the method of the 1^{st} aspect, the glass laminate structure further comprises a third layer adjacent to the second layer opposite the first layer. The third layer is formed from a third glass composition different from the second glass composition. The third glass composition has a third etch rate when exposed to the etching conditions. The third etch rate is different from the second etch rate.

In a 3^{rd} aspect, for the method of the 2^{nd} aspect, the third glass composition is the same as the first glass composition, and the first etch rate is the same as the third etch rate.

In a 4^{th} aspect, for the method of the 2^{nd} aspect, the third glass composition is different from the first glass composition, and the third etch rate is different from the first etch rate.

In a 5^{th} aspect, for the method of the 2^{nd} aspect, the glass laminate structure further comprises a fourth layer adjacent to the third layer opposite the second layer; the fourth layer is formed from a fourth glass composition different from the third glass composition; the fourth glass composition has a fourth etch rate when exposed to the etching conditions; the fourth etch rate is different from the third etch rate.

In a 6^{th} aspect, for the method of any of the 1^{st} through 5^{th} aspects, the etched hole has a first lateral dimension in the first layer and a second lateral dimension in the second layer, and wherein the first lateral dimension is different from the second lateral dimension.

In a 7^{th} aspect, for the method of the 6^{th} aspect, exposing the laminate glass structure to the etching conditions forms the etched hole which further has a third lateral dimension in the third layer, wherein the third lateral dimension is different from the second lateral dimension.

In an 8^{th} aspect, for the method of the 7^{th} aspect, the third lateral dimension is the same as the first lateral dimension.

In a 9th aspect, for the method of the 7^{th} aspect, the third lateral dimension is different from the first lateral dimension.

In a 10^{th} aspect, for the method of the 7^{th} aspect, exposing the laminate glass structure to the etching conditions forms the etched hole which further has a fourth lateral dimension in the fourth layer, wherein the fourth lateral dimension is different from the third lateral dimension.

In a 11^{th} aspect, for the method of any of the 1^{st} through 10^{th} aspects, the difference between the first etch rate and the second etch rate is 5% or more of the first etch rate.

In a 12^{th} aspect, for the method of the 11^{th} aspect, the difference between the first etch rate and the second etch rate is 10% or more of the first etch rate.

In a 13^{th} aspect, for the method of the 12^{th} aspect, the difference between the first etch rate and the second etch rate is 30% or more of the first etch rate.

In a 14^{th} aspect, for the method of any of the 1^{st} through 13^{th} aspects, the first etch rate is greater than the second etch rate.

In a 15^{th} aspect, for the method of the 14^{th} aspect, the etched hole has a morphology comprising an hourglass shape.

In a 16^{th} aspect, for the method of any of the 1^{st} through 13^{th} aspects, the first etch rate is less than the second etch rate.

In a 17^{th} aspect, for the method of the 16^{th} aspect, the etched hole has a morphology comprising a cylindrical shape or a shape where the lateral dimension of the first and third layer are smaller than the lateral dimension of the second layer.

In an 18th aspect, for the method of the 16th aspect, the first layer has an outer surface and the third layer has an outer surface; and the first etch rate is less than the second etch rate.

In a 19^{th} aspect, for the method of the 18^{th} aspect, a mask is formed on the outer surface of the first layer and/or the outer surface of the third layer prior to exposing the laminate glass structure to etching conditions.

In a 20^{th} aspect, for the method of the 19^{th} aspect, the mask forming covers the outer surfaces with a physical masking.

In a 21^{st} aspect, for the method of the 20^{th} aspect, the physical masking is an acid resistant material.

In a 22^{nd} aspect, for the method of the 21^{st} aspect, the acid resistant material is an acid resistant laminate coating.

In a 23^{rd} aspect, for the method of the 22^{nd} aspect, the acid resistant laminate coating is acid resistant tape.

In a 24^{th} aspect, for the method of the 21^{st} aspect, the acid resistant material is an acid resistant deposited coating.

In a 25^{th} aspect, for the method of the 24^{th} aspect, the acid resistant deposited coating is chromium oxi-nitride.

In a 26^{th} aspect, for the method of the 20^{th} aspect, the physical masking has a plurality of holes.

In a 27^{th} aspect, for the method of the 26^{th} aspect, the mask material is printed or deposited over the outer surfaces.

In a 28^{th} aspect, for the method of the 6^{th} aspect, the difference between the first lateral dimension and the second lateral dimension is 5% or more of the first lateral dimension.

In a 29^{th} aspect, for the method of the 28^{th} aspect, the difference between the first lateral dimension and the second lateral dimension is 10% or more of the first lateral dimension.

In an 30^{th} aspect, for the method of any of the 28^{th} through 29^{th} aspects, the first lateral dimension is greater than the second lateral dimension.

In a 31^{st} aspect, for the method of any of the 28^{th} through 29^{th} aspects, the first lateral dimension is less than the second lateral dimension.

In a 32^{nd} aspect, for the method of any of the 1^{st} through 32^{nd} aspects, the method further comprises filling the etched hole with a conductive material.

In a 33^{rd} aspect, for the method of any of the 1^{st} through 32^{nd} aspects, the laminate glass structure is fusion drawn.

In a 34^{th} aspect, for the method of any of the 1^{st} through 33^{rd} aspects, the method further comprises forming the damage track through the laminate glass structure using the laser.

In a 35^{th} aspect, for the method of any of the 1^{st} through 34^{th} aspects, at least one layer in the laminate glass structure is formed from a glass composition that is not photo-machinable.

In a 36^{th} aspect, for the method of the 35^{th} aspect, each layer in the laminate glass structure is formed from a glass composition that is not photo-machinable.

In a 37^{th} aspect, a device comprises: a laminate glass structure comprising: a first layer; a second layer adjacent to the first layer; a third layer adjacent to the second layer opposite the first layer; wherein: the first layer is formed from a first glass composition; the second layer is formed from a second glass composition different from the first glass composition; the third layer is formed from the first glass composition; and a hole through the laminate glass structure has a first lateral dimension in the first layer, a second lateral dimension in the second layer, and a third lateral dimension in the third layer.

In a 38^{th} aspect, for the device of the 37^{th} aspect, the first lateral dimension is at least 5% or more smaller than the second lateral dimension, and the third lateral dimension is at least 5% or more smaller than the second lateral dimension.

In a 39^{th} aspect, for the device of the 37^{th} aspect, the second lateral dimension is at least 5% or more greater of the first lateral dimension and the second lateral dimension is at least 5% or more greater of the third lateral dimension.

In a 40^{th} aspect, for the device of the 38^{th} through 39^{th} aspect, the hole has a morphology comprising a shape where the lateral dimension of the first and third layer are smaller than the lateral dimension of the second layer.

In a 41^{st} aspect, for the device of the 37^{th} aspect, the first lateral dimension is at least 5% or more greater than the second lateral dimension, and the third lateral dimension is at least 5% or more greater than the second lateral dimension.

In a 42^{nd} aspect, for the device of the 37^{th} aspect, wherein the second lateral dimension is at least 5% or more smaller of the first lateral dimension and the second lateral dimension is at least 5% or more smaller of the third lateral dimension.

In a 43^{rd} aspect, for the device of the 41^{st} through 42^{nd} aspect, the hole has a morphology comprising an hourglass shape.

In a 44^{th} aspect, for the device of the 37^{th} aspect, the first lateral dimension is about equal to the second lateral dimension, and the third lateral dimension is about equal to the second lateral dimension.

In a 45^{th} aspect, for the device of the 37^{th} aspect, the second lateral dimension is about equal to the first lateral dimension and the second lateral dimension is about equal to the third lateral dimension.

In a 46^{th} aspect, for the device of the 44^{th} through 45^{th} aspect, the hole has a morphology comprising a cylindrical shape.

In a 47^{th} aspect, for the device of the 37^{th} through 46^{th} aspect, the hole is an etched hole.

In a 48^{th} aspect, for the device of any of the 32^{nd} through 47^{h} aspects, the hole is filled with a conductive material.

In a 49^{th} aspect, for the device of any of the 32^{nd} through 48^{th} aspects, at least one layer in the laminate glass structure is formed from a glass composition that is not photo-machinable.

In a 50^{th} aspect, for the device of the 32^{nd} through 48^{th} aspect, the first glass composition and the second glass composition are not photo-machinable.

### BRIEF DESCRIPTION OF THE DRAWINGS

FIG. 1 shows a cross-section of a laminate glass structure 100 having three layers.

FIG. 2 shows a laminate fusion draw apparatus.

FIG. 3. illustrates a process for etching and filling a via in a single-layer glass structure.

FIG. 4. illustrates a process for etching and filling a via in a two-layer glass laminate structure where the two layers have different etch rates.

FIG. 5 illustrates a process for etching and filling a via in a three-layer glass laminate structure where the second or core layer has a faster etch rate than the first and third or cladding layers.

FIG. 6 illustrates a process for etching and filling a via in a three-layer glass laminate structure where the second or core layer has a slower etch rate than the first and third or cladding layers.

FIG. 7 illustrates a process for etching and filling a via in a five-layer glass laminate structure where each of the five layers have different etch rates, and the resultant via is tapered.

FIG. 8 illustrates a process for etching and filling a via in a five-layer glass laminate structure where the five layers have alternating etch rates.

FIG. 9 illustrates a process for etching and filling a via in a five-layer glass laminate structure where each of the five layers has an etch rate different from adjacent layers, and the resultant via has a pinched waist.

FIG. 10, similar to FIG. 5, illustrates a process for etching and filling a via in a three-layer glass laminate structure where the second or core layer has a faster etch rate than the first and third or cladding layers. FIG. 10 further illustrates that the layers do not necessarily have the same thickness.

FIG. 11 shows top view and 3D view optical microscopy images of the entry and exit of an as-formed via in laminated glass.

FIG. 12 shows 3D and cross-sectional views of fluorescent confocal microscopy images of the as-formed via in laminated glass.

FIG. 13 shows the typical formation of vias through etching in a single component glass and its shape/aspect ratio limitations due to diffusion.

FIG. 14 shows the formation of a via in laminate glass that has been laser damaged and etched having glass compositions resulting in an etch rate ratio of E1/E2<1.

FIG. 15 shows a through via in 1 mm thick laminate glass.

FIG. 16 shows through vias formed in single component laminate glass and multi-component laminate glass.

FIG. 17 shows the process steps of creating a through via in Laminate glasses that require a mask.

FIG. 18 shows a cross-section of a glass substrate, according to one or more embodiments shown and described herein.

FIG. 19 the cross-section of the glass substrate of FIG. 11 being selectively exposed to an etchant through a mask to form cavities in a cladding layer, according to one or more embodiments shown and described herein.

### DETAILED DESCRIPTION

Vias in glass (including glass-ceramic) substrates (or glass laminate structures) typically need to be fully or conformally filled by conducting metals such as copper to provide an electrical pathway. Copper is a particularly desirable conducting metal. In some embodiments, copper is deposited using electroless deposition, or electroless deposition followed by electroplating. Electroless deposition often involves the use of a catalyst, such as Pd. For this type of electroless deposition of copper onto glass, the copper typically does not form a chemical bond to the glass, and instead relies on mechanical interlocking and/or surface roughness for adhesion. More generally, conductive metals such as copper often do not adhere well to glass due to the chemical inertness and low intrinsic roughness of glass materials.

This lack of adhesion can lead to low pull-out strength, and failure mechanisms such as copper falling out of the via hole, or copper pistoning due to differential CTE when a substrate with copper vias is thermally cycled. Described herein are approaches to mitigate some of the issues caused by this lack of adhesion.

Described herein are methods to make TGV using laminate glasses. One method combines a core material with a high etch rate and a clad material with a low etch rate. This design allows this product to have a durable skin layer which can be resistant to chemical (weathering) and mechanical attack to survive in manufacturing processes and extend product lifetime, and in the meanwhile, the less durable core materials enables a much faster etch rate and can significantly shorten process time. In addition, due to the contrasting etch rates between core and clad layers, higher aspect ratio vias can be formed in laminate glasses when compared to similar composition single component glasses.

Another method combines a core material with a low etch rate and a clad material with a high etch rate. This method employs a physical patterned mask that is applied to a less durable cladding layer. The physical mask will allow protection of the cladding layer while in patterned areas diffusion through the thickness of the laminate structure can occur. A physical mask can be utilized when forming TGV in laminates having a cladding glass that is less durable than the core glass. Additionally, this method of masking allows pockets to be formed around or near the TGV. The physical masking can be an acid resistant material in the form of a laminate such as a film or tape. Acid resistant materials should be made of a material does not chemically react with acid including HCl, HNO₃, dilute H₂SO₄, and HF, and does not physically change in response to slight temperature and environmental change. Tapes and films can suitably be an organic polymeric materialthat is resistant to acid, such as polyethylene (PE), polypropylene (PP), polystyrene, polybutylene succinate (PBS), or polytetrafluoroethylene (PTFE). Polymers containing ester (—COOC—), amide (—NH—CO—), imide (—N═CO—) bonds are reactive (decompose) in acid and may not suitable as acid resistant masks. Based on the CTE mismatch between glass and polymer (acid resistant) materials, increased temperature can introduce tension between glass and the mask and leads to the delamination of the physical mask. Laminate polymeric acid resistant materials can be employed in the form of a film, or tape. The physical masking can be an acid resistant acid resistant deposited coating. Examples of deposited coatings include chromium oxi-nitride (CrON) tantalum, nickle (alloys) and silicone. Alternatively, a deposited coating can be a polymeric coating as described above, where the coating is deposited as an ink via an ink printer or screen printer. The physical mask will undergo removal or delamination at the temperature outside of acid etching (working) temperature range and will be removed after the etching is done.

The product produced from these methods consists of laminate glass containing TGV. The TGV can consist of different morphologies, including cylinder and hourglass. The TGV can have top and bottom diameters smaller than the waist diameter. The glass product can have protective cladding remaining, or be of a single composition if all cladding is removed during etch.

### Definitions

As used herein, term “liquidus temperature” refers to the highest temperature at which devitrification occurs in the glass composition.

As used herein, the term “CTE” refers to the coefficient of thermal expansion of the glass composition averaged over a temperature range from about 20° C. to about 300° C.

The term “substantially free,” when used to describe the absence of a particular oxide component in a glass composition, means that the component is present in the glass composition in an amount less than 1 mol. %.

As used herein, the term “glass laminate structure” refers to a specific type of glass substrate that has multiple distinct layers fused together, for example by a fusion draw process.

Where a range of numerical values is recited herein, comprising upper and lower values, unless otherwise stated in specific circumstances, the range is intended to include the endpoints thereof, and all integers and fractions within the range. It is not intended that the scope of the claims be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. Finally, when the term “about” is used in describing a value or an end-point of a range, the disclosure should be understood to include the specific value or end-point referred to. Whether or not a numerical value or end-point of a range recites “about,” the numerical value or end-point of a range is intended to include two embodiments: one modified by “about,” and one not modified by “about.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

The term “or,” as used herein, is inclusive; more specifically, the phrase “A or B” means “A, B, or both A and B.” Exclusive “or” is designated herein by terms such as “either A or B” and “one of A or B,” for example.

The indefinite articles “a” and “an” to describe an element or component means that one or at least one of these elements or components is present. Although these articles are conventionally employed to signify that the modified noun is a singular noun, as used herein the articles “a” and “an” also include the plural, unless otherwise stated in specific instances. Similarly, the definite article “the,” as used herein, also signifies that the modified noun may be singular or plural, again unless otherwise stated in specific instances.

For glass compositions described herein as components of glass structures, the concentration of constituent components (e.g., SiO₂, Al₂O₃, Na₂O and the like) of the glass compositions are given in mole percent (mol. %) on an oxide basis, unless otherwise specified. Glass compositions disclosed herein have a liquidus viscosity which renders them suitable for use in a fusion draw process and, in particular, for use as a glass cladding composition or a glass core composition in a fusion laminate process. As used herein, unless noted otherwise, the terms “glass” and “glass composition” encompass both glass materials and glass-ceramic materials, as both classes of materials are commonly understood. Likewise, the term “glass structure” should be understood to encompass structures containing glasses, glass ceramics, or both.
Laminate Glass Structures and Fusion Drawing

In some embodiments, the properties of a laminate glass structure are exploited to control the shape of an etched hole through the laminate glass structure. A “laminate glass structure” refers to a structure having two or more sheets of glass laminated together to form a stack. One method to fabricate a laminate glass structure is now described. Any suitable method may be used.

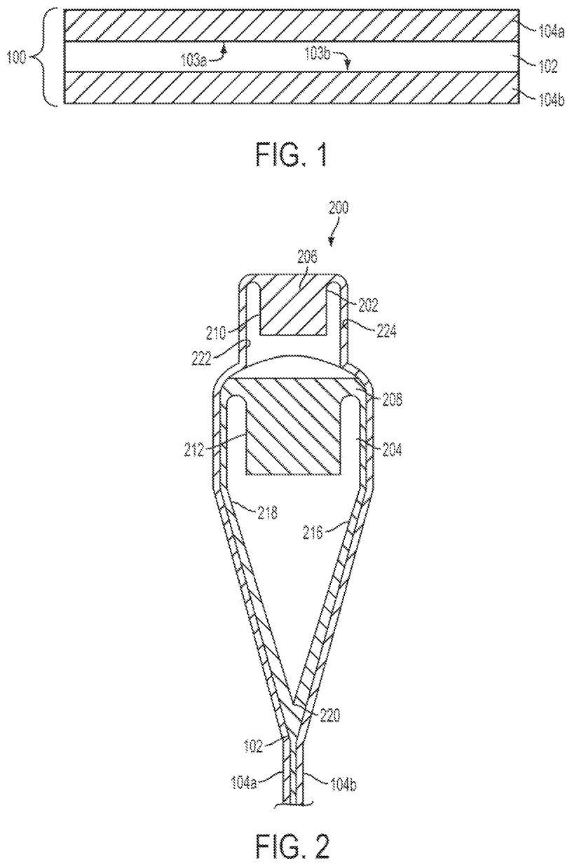

FIG. 1 shows a cross-section of a laminate glass structure 100 having three layers—a core layer 102, a first cladding layer 104a and a second cladding layer 104b. Laminate glass structure 100 generally comprises a core layer 102 formed from a core glass composition. The core layer 102 may be interposed between a pair of cladding layers such as a first cladding layer 104a and a second cladding layer 104b. The first cladding layer 104a and the second cladding layer 104b may be formed from a first cladding glass composition and a second cladding glass composition, respectively. In some embodiments, the first cladding glass composition and the second cladding glass composition may be the same material. In other embodiments, the first cladding glass composition and the second cladding glass composition may be different materials. First cladding layer 104a, core layer 102, and second cladding layer 104b correspond to first, second and third glass layers in some embodiments.

FIG. 1 illustrates the core layer 102 having a first surface 103a and a second surface 103b opposed to the first surface 103a. A first cladding layer 104a is fused directly to the first surface 103a of the core layer, 102 and a second cladding layer 104b is fused directly to the second surface 103b of the core layer 102. The glass cladding layers 104a, 104b are fused to the core layer 102 without any additional materials, such as adhesives, polymer layers, coating layers or the like being disposed between the core layer 102 and the cladding layers 104a, 104b. Thus, the first surface 103a of the core layer 102 is directly adjacent the first cladding layer 104a, and the second surface 103b of the core layer 102 is directly adjacent the second cladding layer 104b. In some embodiments, the core layer 102 and the glass cladding layers 104a, 104b are formed via a fusion lamination process. Diffusive layers (not shown) may form between the core layer 102 and the cladding layer 104a, or between the core layer 102 and the cladding layer 104b, or both.

In some embodiments, the cladding layers 104a, 104b of the glass structures 100 described herein may be formed from a first glass composition having an average cladding coefficient of thermal expansion CTEd a d, and the core layer 102 may be formed from a second, different glass composition which has an average coefficient of thermal expansion CTE_{core}. In some embodiments, the glass compositions of the cladding layers 104a, 104b may have liquidus viscosities of at least 20 kPoise. In some embodiments, the glass compositions of the core layer 102 and the cladding layers 104a, 104b may have liquidus viscosities of less than 250 kPoise.

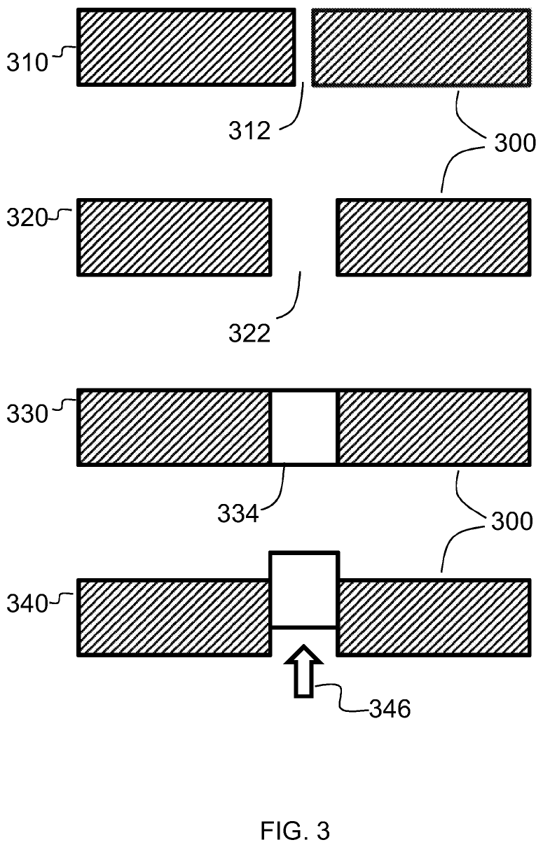

Specifically, the glass structure 100 according to some embodiments herein may be formed by a fusion lamination process such as the process described in U.S. Pat. No. 4,214,886, which is incorporated herein by reference. Referring to FIG. 2 by way of example and further illustration, a laminate fusion draw apparatus 200 for forming a laminated glass article may include an upper isopipe 202 that is positioned over a lower isopipe 204. The upper isopipe 202 may include a trough 210, into which a molten cladding composition 206 may be fed from a melter (not shown). Similarly, the lower isopipe 204 may include a trough 212, into which a molten glass core composition 208 may be fed from a melter (not shown). In the embodiments described herein, the molten glass core composition 208 has an appropriately high liquidus viscosity to be run over the lower isopipe 204.

As the molten glass core composition 208 fills the trough 212, it overflows the trough 212 and flows over the outer forming surfaces 216, 218 of the lower isopipe 204. The outer forming surfaces 216, 218 of the lower isopipe 204 converge at a root 220. Accordingly, the molten core composition 208 flowing over the outer forming surfaces 216, 218 rejoins at the root 220 of the lower isopipe 204, thereby forming a core layer 102 of a laminated glass structure.

Simultaneously, the molten composition 206 overflows the trough 210 formed in the upper isopipe 202 and flows over outer forming surfaces 222, 224 of the upper isopipe 202. The molten composition 206 has a lower liquidus viscosity requirement to be run on the upper isopipe 202, and will have a CTE either equal to or less than the glass core composition 208 when present as a glass. The molten cladding composition 206 is outwardly deflected by the upper isopipe 202 such that the molten cladding composition 206 flows around the lower isopipe 204 and contacts the molten core composition 208 flowing over the outer forming surfaces 216, 218 of the lower isopipe, fusing to the molten core composition and forming cladding layers 104a, 104b around the core layer 102.

In the laminated sheet so formed, the clad thickness may be significantly thinner than the core thickness so that the clad goes into compression and the core into tension. But because the CTE difference is low, the magnitude of the tensile stress in the core will be very low (for example, on the order of 10 MPa or lower) which will allow for the production of a laminated sheet that will be relatively easy to cut off the draw due to its low levels of core tension. Sheets can thus be cut from the laminate structure that is drawn from the fusion draw apparatus. After the sheets are cut, the cut product can then be subjected to a suitable UV light treatment(s), as will be described below in the context of methods for machining the glass structure 100.

As illustrative embodiments, the processes for forming glass structures by fusion lamination described herein with reference to FIGS. 1 and 2 and in U.S. Pat. No. 4,214,886 may be used for preparing glass structures 100 in which the glass cladding layers 104a, 104b have the same glass composition. In other embodiments, the glass cladding layers 104a, 104b of the glass structure 100 may be formed from different glass compositions. Non-limiting exemplary processes suitable for forming glass structures having glass cladding layers of different compositions are described in commonly-assigned U.S. Pat. No. 7,514,149, which is incorporated herein by reference in its entirety.
Glass Composition and Different Etch Rates

The different layers of a laminate glass structure may be formed of different glass compositions having different etch rates. The compositions shown in Table 1 are all suitable for use in the fusion drawing process described herein. Further, the compositions shown in Table 1 can be used as the clad layer or the core layer. For example, they have Tg and viscosity profiles suitable for fusion draw processes.

TABLE 1
(Ex. 1-10)

| Composition | | | | | | | | | | |
|---|---|---|---|---|---|---|---|---|---|---|
| in mol % | Ex 1 | Ex 2 | Ex 3 | Ex 4 | Ex 5 | Ex 6 | Ex 7 | Ex 8 | Ex 9 | Ex 10 |
| SiO₂ | 69.49 | 69.27 | 67.50 | 64.35 | 64.90 | 57.84 | 63.60 | 76.44 | 66.65 | 66.29 |
| Al₂O₃ | 10.29 | 10.58 | 12.70 | 13.95 | 13.90 | 16.53 | 15.67 | 5.18 | 12.39 | 12.19 |
| B₂O3 | 0.00 | 0.00 | 3.70 | 7.00 | 5.10 | 0.00 | 0.00 | 0.00 | 7.85 | 6.52 |
| P2O5 | 0.00 | 0.00 | 0.00 | 0.00 | 0.00 | 6.45 | 2.48 | 0.00 | 0.00 | 0.00 |
| Na₂O | 14.01 | 14.76 | 13.60 | 14.01 | 13.60 | 16.53 | 10.81 | 11.67 | 0.00 | 0.00 |
| K₂O | 1.16 | 0.01 | 0.00 | 0.52 | 0.00 | 0.00 | 0.00 | 0.00 | 0.00 | 0.00 |
| Li₂O | 0.00 | 0.00 | 0.00 | 0.00 | 0.00 | 0.00 | 6.24 | 0.00 | 0.00 | 0.00 |
| MgO | 6.20 | 5.27 | 2.40 | 0.05 | 2.40 | 2.61 | 0.00 | 6.61 | 2.83 | 6.03 |
| CaO | 0.51 | 0.00 | 0.00 | 0.00 | 0.00 | 0.00 | 0.00 | 0.00 | 8.44 | 5.33 |
| ZnO | 0.00 | 0.00 | 0.00 | 0.00 | 0.00 | 0.00 | 1.16 | 0.00 | 0.00 | 0.00 |
| BaO | 0.00 | 0.00 | 0.00 | 0.00 | 0.00 | 0.00 | 0.00 | 0.00 | 0.00 | 2.11 |
| ZrO₂ | 0.01 | 0.01 | 0.00 | 0.01 | 0.00 | 0.00 | 0.00 | 0.00 | 0.00 | 0.00 |
| SnO₂ | 0.19 | 0.11 | 0.09 | 0.09 | 0.07 | 0.05 | 0.04 | 0.10 | 0.08 | 0.08 |
| SrO | 0.00 | 0.00 | 0.00 | 0.00 | 0.00 | 0.00 | 0.00 | 0.00 | 1.76 | 1.45 |
| Fe₂O₃ | 0.01 | 0.01 | 0.00 | 0.03 | 0.00 | 0.00 | 0.00 | 0.00 | 0.00 | 0.00 |
| Etch Rate 1.45M | 0.68 | 0.74 | 0.91 | 1.51 | 1.30 | 2.44 | 1.36 | 0.13 | 0.38 | 0.37 |
| HF, room temp., | | | | | | | | | | |
| Static (microns/ | | | | | | | | | | |
| min/2sides) | | | | | | | | | | |

TABLE 1
(Ex. 11-17)

| Composition | | | | | | | | Ex 1-17 range | |
|---|---|---|---|---|---|---|---|---|---|
| in mol % | Ex 11 | Ex 12 | Ex 13 | Ex 14 | Ex 15 | Ex 16 | Ex 17 | min | max |
| SiO₂ | 67.54 | 69.76 | 71.46 | 70.41 | 71.89 | 67.51 | 70.54 | 57.84 | 76.44 |
| Al₂O₃ | 11.02 | 12.02 | 12.40 | 13.31 | 12.31 | 6.48 | 8.03 | 5.18 | 16.53 |
| B₂O3 | 9.79 | 3.21 | 2.52 | 1.78 | 0.66 | 19.67 | 9.17 | 0.00 | 19.67 |
| P2O5 | 0.00 | 0.00 | 0.00 | 0.00 | 0.00 | 0.00 | 2.45 | 0.00 | 6.45 |
| Na₂O | 0.00 | 0.00 | 0.00 | 0.00 | 0.00 | 0.00 | 6.29 | 0.00 | 16.53 |
| K₂O | 0.00 | 0.00 | 0.00 | 0.00 | 0.00 | 0.00 | 0.00 | 0.00 | 1.16 |
| Li₂O | 0.00 | 0.00 | 0.00 | 0.00 | 0.00 | 0.00 | 3.42 | 0.00 | 6.24 |
| MgO | 2.28 | 4.71 | 3.52 | 4.07 | 4.97 | 0.53 | 0.00 | 0.00 | 6.61 |
| CaO | 8.77 | 5.81 | 5.24 | 5.34 | 5.29 | 5.27 | 0.00 | 0.00 | 8.77 |
| ZnO | 0.00 | 0.00 | 0.00 | 0.00 | 0.00 | 0.00 | 0.00 | 0.00 | 1.16 |
| BaO | 0.00 | 3.17 | 3.39 | 3.78 | 3.34 | 0.00 | 0.00 | 0.00 | 3.78 |
| ZrO₂ | 0.00 | 0.00 | 0.00 | 0.00 | 0.00 | 0.00 | 0.00 | 0.00 | 0.01 |
| SnO₂ | 0.08 | 0.08 | 0.09 | 0.09 | 0.09 | 0.05 | 0.10 | 0.04 | 0.19 |
| SrO | 0.53 | 1.23 | 1.38 | 1.22 | 1.45 | 0.50 | 0.00 | 0.00 | 1.76 |
| Fe₂O₃ | 0.00 | 0.00 | 0.00 | 0.00 | 0.00 | 0.00 | 0.00 | 0.00 | 0.03 |
| Etch Rate 1.45M | 0.34 | 0.34 | 0.27 | 0.34 | 0.30 | 0.528 | 0.281 | 0.13 | 2.44 |
| HF, room temp., | | | | | | | | | |
| Static (microns/ | | | | | | | | | |
| min/2sides) | | | | | | | | | |

TABLE 2
(Ex 18)

| Composition | | |
|---|---|---|
| in mol % | clad | core |
| SiO₂ | 50.9 | 66.3 |
| Al₂O₃ | 21.0 | 13.7 |
| B₂O₃ | 14.8 | 0.0 |
| CaO | 0.0 | 0.5 |
| Na₂O | 12.9 | 13.4 |
| K₂O | 0.0 | 1.7 |
| MgO | 0.0 | 3.9 |
| SrO | 0.0 | 0.0 |
| SnO₂ | 0.2 | 0.5 |
| BaO | 0.0 | 0.0 |
| Fe₂O₃ | 0.0 | 0.0 |
| total | 100.00 | 100.00 |

TABLE 3
(Ex 19)

| Composition | | |
|---|---|---|
| in mol % | clad | core |
| SiO₂ | 78.64 | 73.71 |
| Al₂O₃ | 1.92 | 6.83 |
| B₂O₃ | 14.46 | 0.00 |
| P₂O₅ | 0.00 | 0.00 |
| CaO | 0.86 | 0.00 |
| Li₂O | 0.00 | 0.00 |
| Na₂O | 3.45 | 12.01 |
| K₂O | 0.00 | 2.74 |
| MgO | 0.00 | 4.51 |
| SrO | 0.00 | 0.00 |
| SnO₂ | 0.10 | 0.19 |
| BaO | 0.57 | 0.00 |
| ZnO | 0.00 | 0.00 |
| total | 100.00 | 100.00 |

None of the compositions shown in Table 1 are photo-machinable. So, processes that rely on a glass being photo-machinable to form complex shapes will be inapplicable to these glass compositions.

The glass compositions of Table 1 may be mixed and matched in a wide variety of combinations of layers, to form a glass laminate structure with desired differential etch rates in various layers.
Laser Damage Track/Laser Drill and Etch

In some embodiments, complex via shapes may be formed using a simple process involving a single laser damage (or drill) and etch process.
Damage Region/Hole Formation

In some embodiments, a high energy laser pulse or pulses may be applied to create damage regions through the substrate. Damage regions allows etchant to flow therein during downstream etching processes. In some embodiments, damage regions may be a line of laser-induced damage formed by a pulsed laser. The pulsed laser may form the damage line by non-linear multi-photon absorption, for example. When subsequently etched, the damage region allows etchant to penetrate the substrate. And, the rate of material removal within such a damage region 120 is faster than the rate of material removal outside damage region. Exemplary ways for performing the laser damage creation and subsequent etching are disclosed in U.S. Pat. No. 9,278,886, US Pub. No. 2015/0166393, U.S. Pub. No. 2015/0166395, and U.S. Application 62/633,835, “Alkali-Free Borosilicate Glasses with Low Post-HF Etch Roughness,” filed Feb. 22, 2018, each of which is hereby incorporated by reference in its entirety. In some embodiments, a laser may be used to form an ablated hole instead of damage regions, and the ablated hole may be widened by etching. Any suitable method of forming a pilot hole or damage region through the laminate glass structure may be used.
Etching

Damage regions or holes can be etched to form vias. Etching processes may include submerging the glass article in an etchant bath. Additionally, or alternatively, etchant may be sprayed onto the glass article. The etchant may remove material of the substrate to enlarge damage regions or holes. Any suitable etchants and etching methods may be utilized. Non-limiting examples of etchants include strong mineral acids such as nitric acid, hydrochloric acid, acylic acid or phosphoric acid; fluorine containing etchants such as hydrofluoric acid, ammonium bifluoride, sodium fluoride, and the like; and mixtures thereof. In some embodiments, the etchant is hydrofluoric acid.

A glass surface that has been etched has distinctive structural characteristics, and one of skill in the art can tell from inspecting a glass surface whether that surface has been etched. Etching often changes the surface roughness of the glass. So, if one knows the source of the glass and the roughness of that source, a measurement of surface roughness can be used to determine whether the glass has been etched. In addition, etching generally results in differential removal of different materials in the glass. This differential removal can be detected by techniques such as electron probe microanalysis (EPMA).
Via Shape

FIG. 3 through FIG. 10 show schematics of different shapes that may be obtained using the processes described herein.

FIG. 3. illustrates a process for etching and filling a via in a single-layer substrate. FIG. 3 shows glass substrate 300 at different points in the process. Illustration 310 shows glass substrate 300 after hole 312 has been formed, for example by a laser ablation process. A damage track (not illustrated) could instead be present instead of hole 312. Illustration 320 shows glass substrate 300 after an etching step. Because substrate 300 is not a glass laminate structure but is rather a single piece of glass without distinct layers, the etching has resulted in a hole 322 with a shape unaffected by differential etch rates in different layers. Illustration 330 shows substrate 300 after via 334 has been formed in hole 322. Via 334 is a conductive metal such as copper. Illustration 340 shows a problem with via 334—due to the cylindrical shape of hole 322, and the low adhesion of copper to glass, force 346 can cause via 334 to slide out of hole 322.

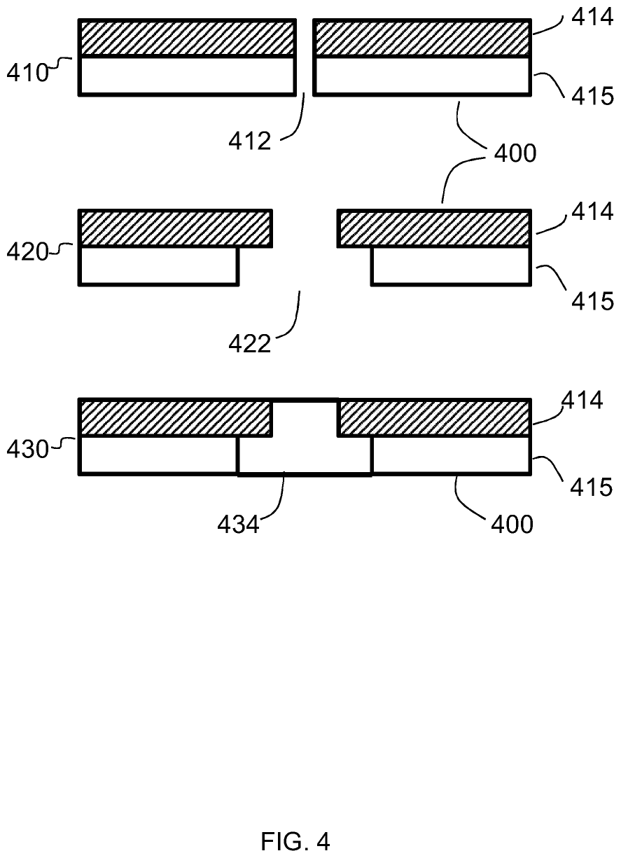

FIG. 4. illustrates a process for etching and filling a via in a two-layer glass laminate structure, where the two layers have different etch rates. FIG. 4 shows glass substrate 400, which is a glass laminate structure, at different points in the process. Glass substrate 400 has two distinct layers, a first layer 414 and a second layer 415. In the example of FIG. 4, first layer 414 has an etch rate slower than that of second layer 415 for the etching conditions used. Illustration 410 shows glass substrate 400 after hole 412 has been formed, for example by a laser ablation process. A damage track (not illustrated) could instead be present instead of hole 412. Illustration 420 shows glass substrate 400 after an etching step. Due to the different etch rates, hole 422 is wider in first layer 414 than in second layer 415. Illustration 430 shows substrate 400 after via 434 has been formed in hole 422.

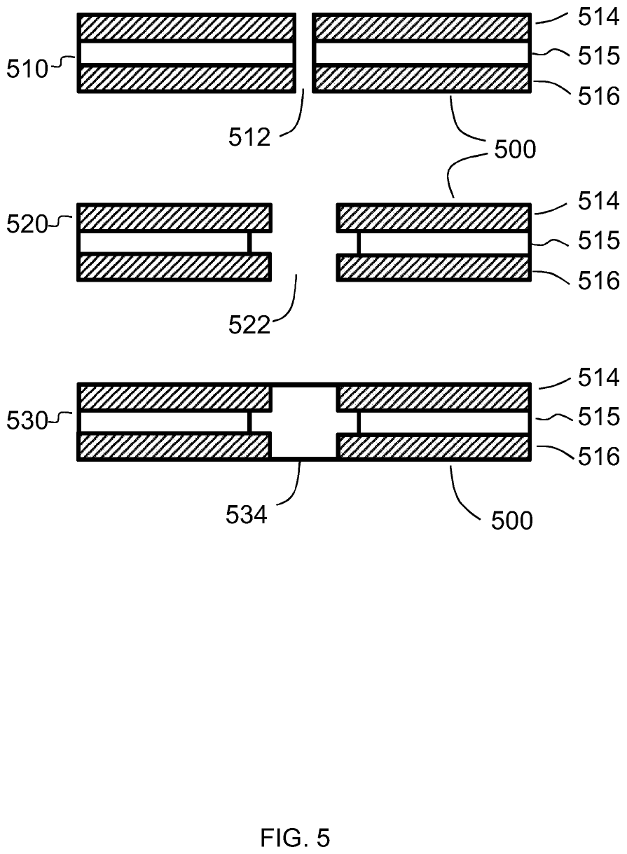

FIG. 5 illustrates a process for etching and filling a via in a three-layer substrate where the second or core layer has a faster etch rate than the first and third or cladding layers. FIG. 5 shows glass substrate 500, which is a glass laminate structure, at different points in the process. Glass substrate 500 has three distinct layers, a first layer 514, a second layer 515, and a third layer 516. In the example of FIG. 5, first layer 514 and third layer 516 have slower etch rates than second layer 515 for the etching conditions used. Illustration 510 shows glass substrate 500 after hole 512 has been formed, for example by a laser ablation process. A damage track (not illustrated) could instead be present instead of hole 512. Illustration 520 shows glass substrate 500 after an etching step. Due to the different etch rates, hole 522 is wider in second layer 515 than in first layer 514 and third layer 516. Illustration 530 shows substrate 500 after via 534 has been formed in hole 522.

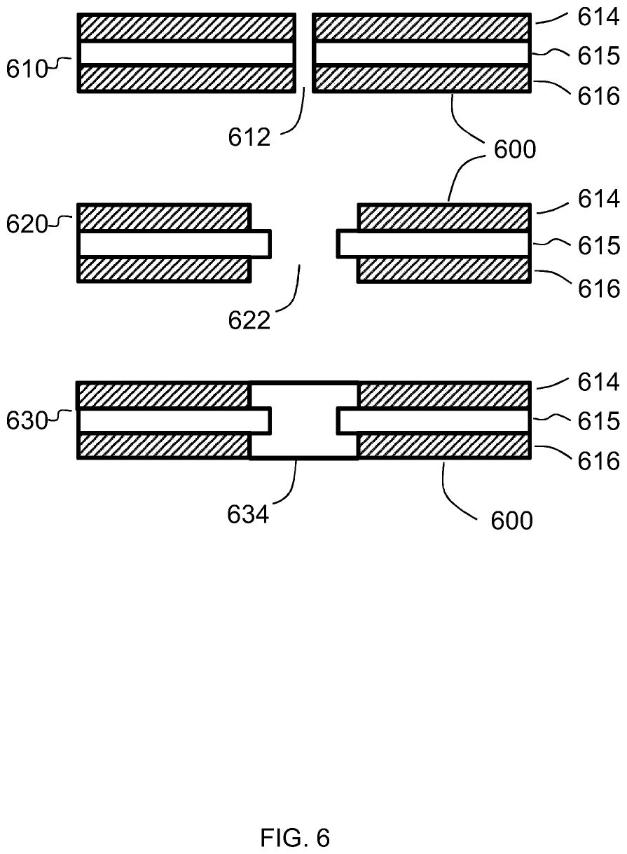

FIG. 6 illustrates a process for etching and filling a via in a three-layer substrate where the second or core layer has a slower etch rate than the first and third or cladding layers. FIG. 6 shows glass substrate 600, which is a glass laminate structure, at different points in the process. Glass substrate 600 has three distinct layers, a first layer 614, a second layer 615, and a third layer 616. In the example of FIG. 6, first layer 614 and third layer 616 have faster etch rates than second layer 615 for the etching conditions used. Illustration 610 shows glass substrate 600 after hole 612 has been formed, for example by a laser ablation process. A damage track (not illustrated) could instead be present instead of hole 612. Illustration 620 shows glass substrate 600 after an etching step. Due to the different etch rates, hole 622 is narrower in second layer 615 than in first layer 614 and third layer 616. Illustration 630 shows substrate 600 after via 634 has been formed in hole 622.

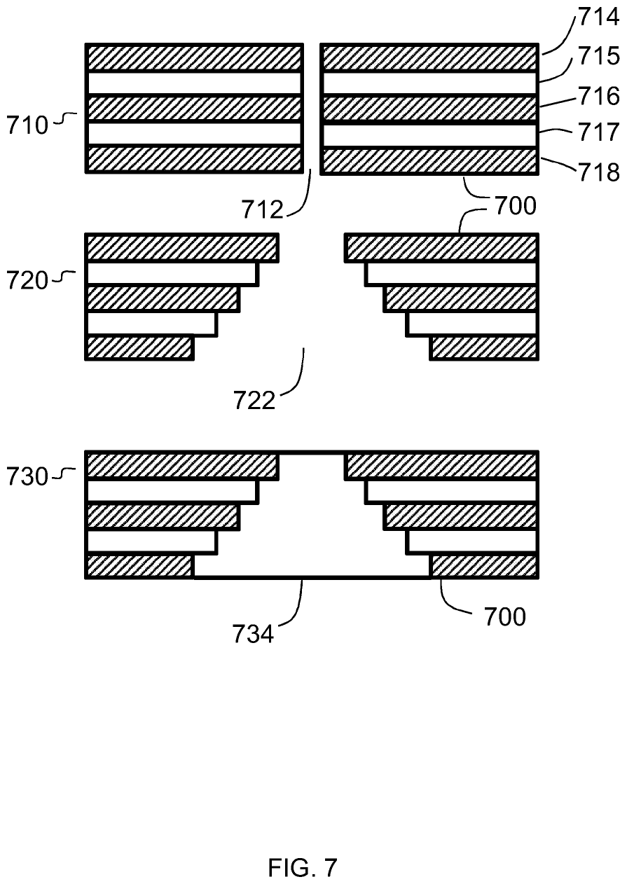

FIG. 7 illustrates a process for etching and filling a via in a five-layer substrate where each of the five layers have different etch rates, and the resultant via is tapered. FIG. 7 shows glass substrate 700, which is a glass laminate structure, at different points in the process. Glass substrate 700 has five distinct layers, a first layer 714, a second layer 715, a third layer 716, a fourth layer 717 and a fifth layer 718. In the example of FIG. 7, the etch rates become faster layer by layer moving across the five layers from first layer 714 (slowest etch rate) to fifth layer 718 (fastest etch rate) for the etching conditions used. Illustration 710 shows glass substrate 700 after hole 712 has been formed, for example by a laser ablation process. A damage track (not illustrated) could instead be present instead of hole 712. Illustration 720 shows glass substrate 700 after an etching step. Due to the different etch rates, hole 722 is narrowest in first layer 715, and becomes progressively wider moving across the five layers to fifth layer 718. Illustration 730 shows substrate 700 after via 734 has been formed in hole 722.

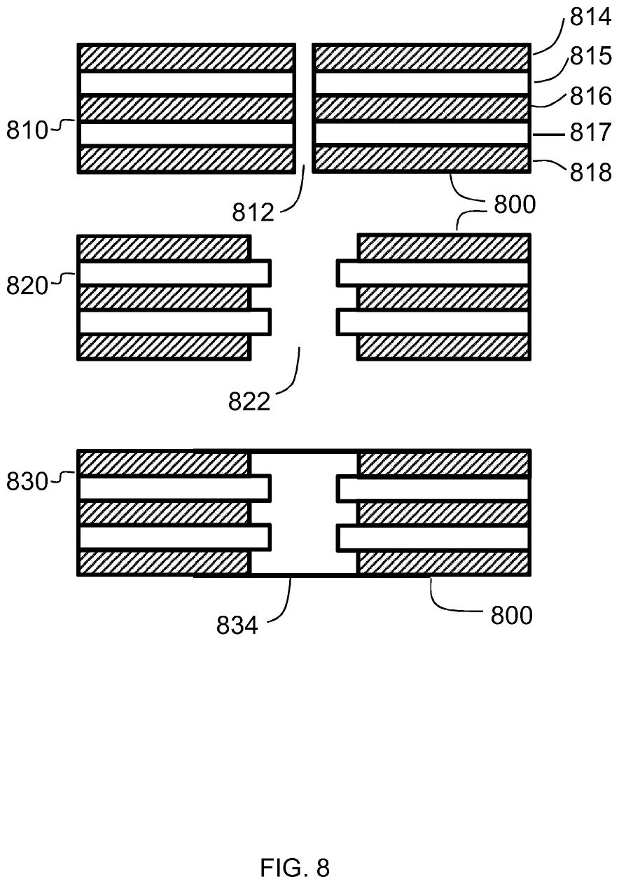

FIG. 8 illustrates a process for etching and filling a via in a five-layer substrate where the five layers have alternating etch rates. FIG. 8 shows glass substrate 800, which is a glass laminate structure, at different points in the process. Glass substrate 800 has five distinct layers, a first layer 814, a second layer 815, a third layer 816, a fourth layer 817 and a fifth layer 818. In the example of FIG. 8, the etch rates alternate between faster in first layer 814, third layer 816 and fifth layer 818, and slower in second layer 815 and fourth layer 817, for the etching conditions used. Illustration 810 shows glass substrate 800 after hole 812 has been formed, for example by a laser ablation process. A damage track (not illustrated) could instead be present instead of hole 812. Illustration 820 shows glass substrate 800 after an etching step. Due to the different etch rates, hole 822 alternates between wider in first layer 814, third layer 816 and fifth layer 818, and narrower in second layer 815 and fourth layer 817. Illustration 830 shows substrate 800 after via 834 has been formed in hole 822.

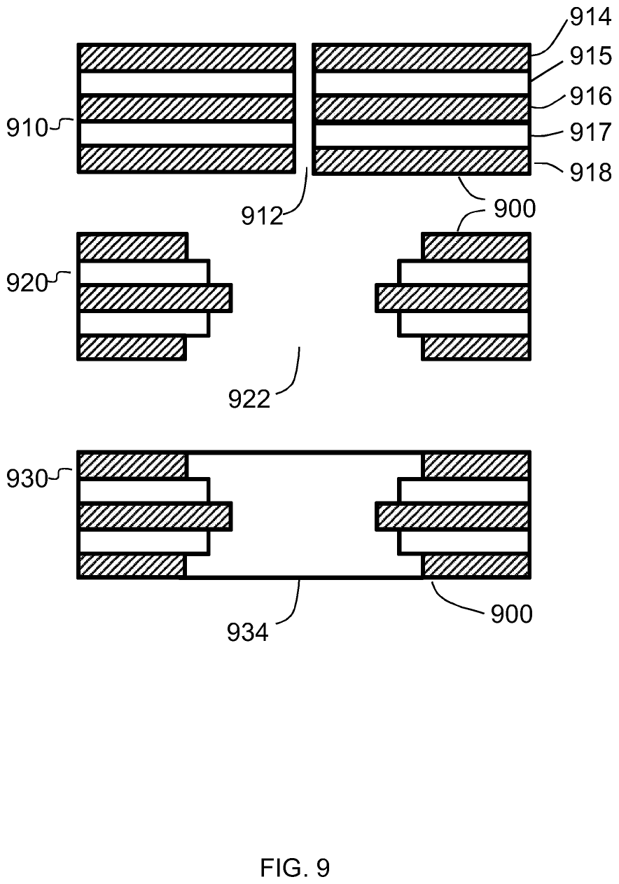

FIG. 9 illustrates a process for etching and filling a via in a five-layer substrate where each of the five layers has an etch rate different from adjacent layers, and the resultant via has a pinched waist. Glass substrate 900 has five distinct layers: a first layer 914, a second layer 915, a third layer 916, a fourth layer 917 and a fifth layer 918. In the example of FIG. 9, the etch rate is slowest in the centermost third layer 916, and increase progressively in layers closer to the surfaces of substrate 900, with the fastest etch rates in first layer 914 and fifth layer 918. Illustration 910 shows glass substrate 900 after hole 912 has been formed, for example by a laser ablation process. A damage track (not illustrated) could instead be present instead of hole 912. Illustration 920 shows glass substrate 900 after an etching step. Due to the different etch rates, hole 922 is narrowest in centermost third layer 916, and becomes progressively wider moving outwards towards first layer 914 and fifth layer 918, where hole 922 is widest. Illustration 930 shows substrate 900 after via 934 has been formed in hole 922.

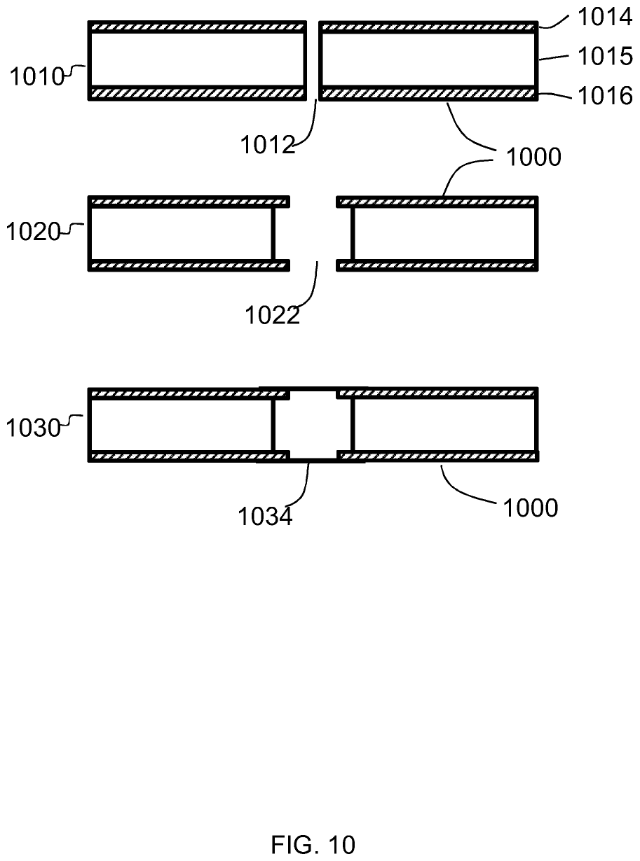

FIG. 10, similar to FIG. 5, illustrates a process for etching and filling a via in a three-layer substrate where the second or core layer has a faster etch rate than the first and third or cladding layers. FIG. 10 further illustrates that the layers do not necessarily have the same thickness. FIG. 10 shows glass substrate 1000, which is a glass laminate structure, at different points in the process. Glass substrate 1000 has three distinct layers, a first layer 1014, a second layer 1015, and a third layer 1016. In the example of FIG. 10, first layer 1014 and third layer 1016 have slower etch rates than second layer 1015 for the etching conditions used. Illustration 1010 shows glass substrate 1000 after hole 1012 has been formed, for example by a laser ablation process. A damage track (not illustrated) could instead be present instead of hole 1012. Illustration 1020 shows glass substrate 1000 after an etching step. Due to the different etch rates, hole 1022 is wider in second layer 1015 than in first layer 514 and third layer 516. Illustration 530 shows substrate 500 after via 534 has been formed in hole 522.

FIG. 3 through FIG. 10 illustrate the use of layers in a glass laminate structure with different etch rates being used to create non-cylindrical hole shapes. But, such layers may also be used to create cylindrical shapes. For example, a narrow hole in a uniform substrate (without laminate layers having different glass composition) exposed to etchant may lead to a pinched or hourglass shape, with a waist narrower than the openings at the substrate surface. This occurs because transport effects may affect etch rate at different parts of the hole, depending on the relative rates of transport and surface phenomena. For example, the rate of transport of reactive species to the center of the substrate may result in a slower etch rate at the center. Similarly, the rate of transport of reaction products from the center of the substrate may also result in a slower etch rate, if the reaction products slow etch rate. These effects can be compensated for using a laminate structure having a center layer (or layers) with a faster etch etch rate than outer layers. For example, substrate 500 of FIG. 5, if used in a context where a single-layer substrate would have a waist, would result in a reduced waist and more cylindrical geometry.
Substrate, Layer and Via Dimensions

In some embodiments, the diameter of the hole changes as a function of axial position. For example, the diameter of hole 522 in FIG. 5 changes from smaller in layer 514 to larger in layer 515 back to smaller in layer 516. The hole has a maximum diameter (for example, the diameter in layer 515) and a minimum diameter (for example, the diameter in layers 514 and 516). If the hole is not circular, the “diameter” of the hole is the diameter of a circle having the same cross-sectional area as the hole, in a plane normal to the axial direction.

In some embodiments, the minimum diameter as a percentage of the maximum diameter may be 1%, 5%, 10%, 15%, 20%, 25%, 30%, 35%, 40%, 45%, 50%, 55%, 60%, 65%, 70%, 75%, 80%, 90%, 99% or any range having any two of these values as endpoints, including endpoints. In some embodiments, the minimum diameter is 50% to 100% of the maximum diameter.

The hole may have any suitable axial length. The axial length of a hole corresponds to the thickness of the substrate near the hole. As non-limiting examples, the thicknesses of the substrate (and axial hole length) may be 10 μm, 60 μm, 120 μm, 180 μm, 240 μm, 300 μm, 360 μm, 420 μm, 480 μm, 540 μm, 600 μm, 720 μm, 840 μm, 960 μm, 1080 μm, 1500 μm, 2000 μm, or any range having any two of these values as endpoints, including endpoints. In some embodiments, the thickness of the substrate and the axial hole length is 10 μm to 2000 μm, or 240 μm to 360 μm, or 600 μm to 1500 μm.

The layers of glass within the substrate may have any suitable thickness. Each layer within a substrate may have the same thickness. Or, some layers may have a thickness different from the others. As non-limiting examples, the thicknesses of individual layers may be 0.1 μm, 1 μm, 5 μm, 10 μm, 60 μm, 120 μm, 180 μm, 240 μm, 300 μm, 360 μm, 420 μm, 480 μm, 540 μm, 600 μm, 720 μm, 840 μm, 960 μm, 1080 μm, or 1500 μm, or any range having any two of these values as endpoints, including endpoints. In some embodiments, the outermost layers each have a thickness of 10 μm to 120 μm, and a single inner or core layer has a thickness of 480 μm to 840 μm.

Via 110 may have any suitable minimum diameter and maximum diameter. As non-limiting examples, these diameters may be 10 μm, 20 μm, 30 μm, 40 μm, 50 μm, 60 μm, 70 μm, 80 μm, 90 μm, 100 μm, 120 μm, 140 μm, 160 μm, 180 μm, 200 μm, or any range having any two of these values as endpoints, including endpoints. In some embodiments, the maximum via diameter may be 10 μm to 200 μm, or 40 μm to 60 μm. In some embodiments, the maximum via diameter may be 10 μm to 200 μm, or 40 μm to 60 μm.

High aspect ratio vias with a via length of 240 μm to 360 μm and a maximum via diameter of 40 μm to 60 μm are particularly desirable for certain applications at the present time. “Aspect ratio” as used herein refers to the ratio of the via length to the maximum via diameter.

Via 110 may have any suitable aspect ratio. As non-limiting examples, the aspect ratio may be 1, 2, 3, 4, 5, 6, 7, 8, 9, 10, 11, 12, 13, 14, 15, 16, 17, 18, 19, 20, 25, 30, 40 or any range having any two of these values as endpoints, including endpoints. In some embodiments, the aspect ratio may be 4 to 8, 12 to 20, or 14 to 18.

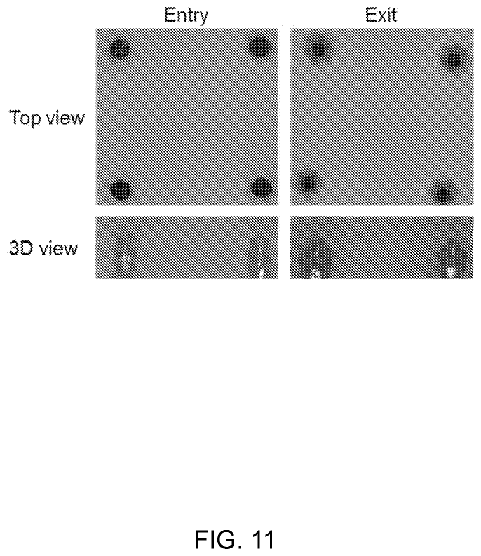

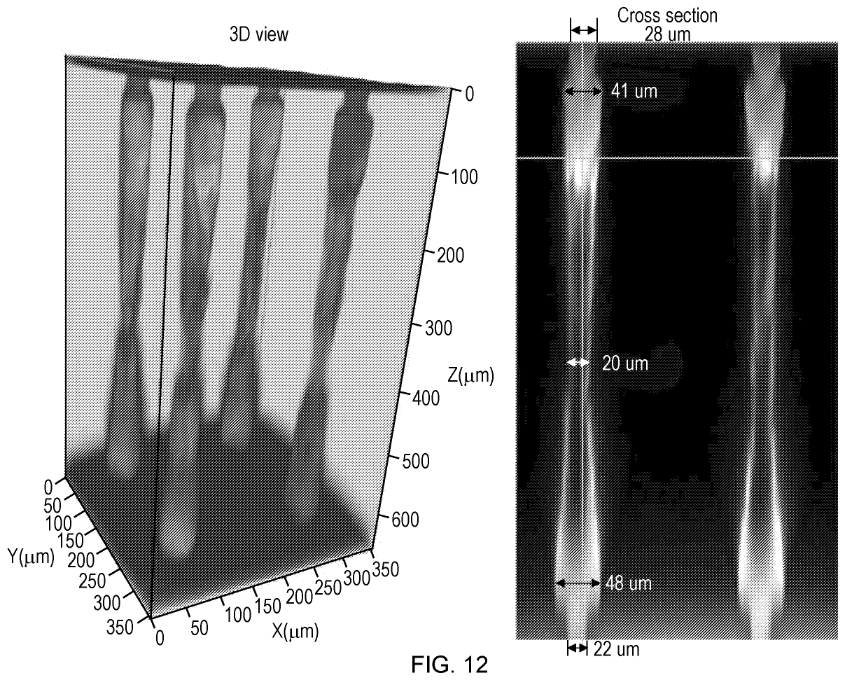

In some embodiments, such as those described in the examples of FIG. 11 and FIG. 12, a high substrate thickness of 600 μm to 1500 μm is combined with a maximum via diameter of 40 μm to 60 μm. Such a via may have an aspect ratio, for example, of 14.58 as in FIG. 12, or 12 to 20, or 14 to 18. Such a via may further have a minimum diameter as a percentage of maximum diameter, for example, of 42% as in FIG. 12, or 40% to 100%. Achieving high aspect ratios in conjunction with a high minimum diameter as a percentage of maximum diameter in the size ranges described can be difficult. A high aspect ratio means that the parts of the hole in the middle of the substrate etch more slowly than parts near the surface due to transport kinetics, which leads to “pinching” of the hole—a small minimum diameter in the middle of the substrate, relative to a significantly higher maximum diameter near the surface. The use of a faster-etching material in the middle of the substrate and a slower-etching material near the surface may mitigate this effect, as illustrated in the example of FIG. 12.

It is expected that the desirable dimensions will change in the future, and that the concepts described herein may be used to provide appropriate holes and vias for those dimensions.

Unless otherwise specified, dimensions described herein are measured using: (1) optical microscopy for external features such as substrate thickness and via diameter at the surface of the substrate; and (2) fluorescent confocal microscopy images for internal features, such as via diameter inside the substrate.
Metallizing

After vias are formed, they may optionally coated and/or filled with a conductive material, for example through metallization. The metal or conductive material can be, for example copper, aluminum, gold, silver, lead, tin, indium tin oxide, or a combination or alloy thereof. The process used to metalize the interior of the holes can be, for example, electro-plating, electroless plating, physical vapor deposition, or other evaporative coating methods. The holes may also be coated with catalytic materials, such as platinum, palladium, titanium dioxide, or other materials that facilitate chemical reactions within the holes.
TGV in Laminate Glass

Corning has developed through glass vias (TGV) processing technology to create either through vias in glass substrates. This technology can produce TGV in laminate glasses composed of fast-etching clad and slow-etching core and laminate glasses composed of slow-etching clad and fast-etching core. The present disclosure provides methods of making glass through vias from laminate glass substrate in a shortened time compared to single glass compositions, wherein the glass vias have unique and improved shapes. The TGV forming methods according embodiments discussed herein are capable of forming TGV in laminate glass have the added complexity of having layers of differing etch rates between the core glass and the exterior cladding glass. The method used to create the TGV depends on the chemistries of the two combined glasses used to form the laminate.

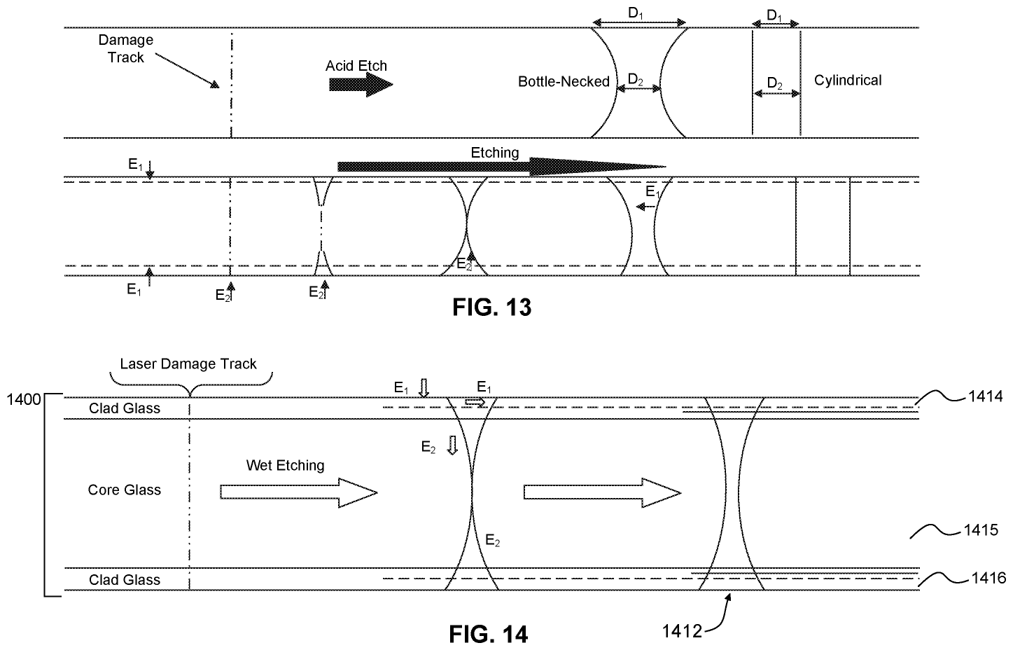

The invention to be described is a process by which a TGV is made in a laminate glass structure. FIG. 13 shows the typical formation of TGV through etching in a single component glass and its shape/aspect ratio limitations due to diffusion. FIG. 14 shows the process by which a TGV is made in a laminate glass structure 1400 is accomplished by adjusting the glass compositions of the clad 1414 and 1416 and core 1415 layers to exhibit a favorable etch rate ratio between the two. If the etch rates of the Clad 1414 and 1416 (E1) and the Core 1415 (E2) are equal then the etch rate ratio between the two is represented as E1/E2=1. In this case, the laminate glass acts as a single component glass, having the same diffusion limited aspect ratio restrictions as a single component glass. To increase diffusion/penetration of the modified region, it is best to have a core layer 1415 composition that has a higher etch rate than that of a durable cladding layer 1414 and 1416. This would be a clad to core etch rate ratio of less than one represented as E1/E2<1. Depending on desired thickness of substrate and application either of these ratios are acceptable to form vias in laminate glasses resulting in a necessary etch rate ratio as E1/E2<1.

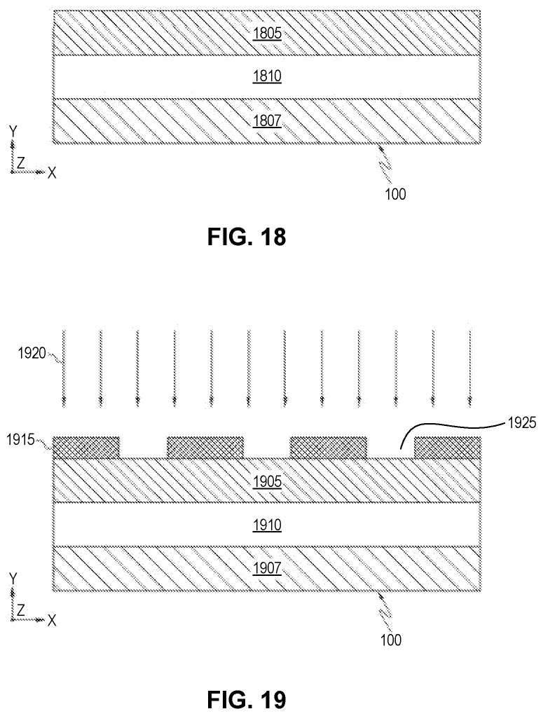

Referring to FIG. 18, the glass substrate 100 is depicted, including the upper glass cladding layer 1805, the lower glass cladding layer 1807, and the glass central core 1810. As described above, the glass compositions of the upper glass cladding layer 1805, the lower glass cladding layer 1807, and the glass central core 1810 can vary such that the durability of the upper glass cladding layer 1805, the lower glass cladding layer 1807, and the glass central core 1810 in an etchant varies. For example, it can be desirable for one or both of the upper glass cladding layer 1805 and lower glass cladding layer 1807 to have a dissolution rate in the etchant that is different than the glass central core 1810.

Referring to FIG. 19, cavities or wells 1925 are formed in the glass substrate 100 to transform the glass substrate into a structured article as described herein. The cavities or wells 1925 can be formed in the surface of the glass substrate 100 using the process depicted in FIG. 12. In some embodiments, the process comprises forming a mask 1915 on a surface of the glass substrate 100. For example, the mask 1915 is formed on the surface of the upper glass cladding layer 105 and/or the lower glass cladding layer 107. The mask 1915 can be formed by printing (e.g., inkjet printing, gravure printing, screen printing, or another printing process) or another deposition process. In some embodiments, the mask 1915 is resistant to the etchant (e.g., the etchant that will be used to etch the cavities or wells 1925 in the glass substrate 100). For example, the mask 1915 can comprise an acrylic ester, a multifunctional acrylate n vinylcaprolactam, or another suitable mask material. In some embodiments, the mask 1915 is formed from an ink material comprising a primer to enhance adhesion between the mask and the glass substrate 100. Such enhanced adhesion can reduce seepage of the etchant between the mask 1915 and the glass substrate 100, which can help to enable the precise cavities described herein.

In some embodiments, the mask 1915 comprises one or more open regions at which the glass substrate 100 remains uncovered. The open regions of the mask 1915 can have a pattern corresponding to the desired pattern of the cavities or wells 1925 to be formed in the glass substrate 100. For example, the pattern of the mask 1915 can be an array of regularly repeating rectangular shapes (e.g., to receive microprocessors/electronic components as described herein). In such embodiments, the shapes patterned by the mask 1915 can correspond closely to the shape of the microprocessors/electronic components. Other shapes also can be used, and the shapes can correspond closely to the shape of the electronic components or be capable of securely holding the electronic components in position on the glass substrate 100. Thus, the mask 1915 can be configured as an etch mask to enable selective etching of the upper glass cladding layer 1905 and/or the lower glass cladding layer 1907 and form the cavities or wells 1925 in the glass substrate 100 as described herein.

In some embodiments, the glass substrate 100 with the mask 1915 disposed thereon is exposed to the etchant 1920. For example, the upper glass cladding layer 1905 and/or the lower glass cladding layer 1907 is contacted with the etchant 1920 as shown in FIG. 19, thereby selectively etching an exposed portion of the respective glass cladding layer that is uncovered by the mask 1915 and forming the cavities or wells 1925 in the glass substrate, thereby transforming the substrate into the shaped article. In some embodiments, the glass substrate 100 with the mask 1915 disposed thereon is exposed to the etchant 1920 at an etching temperature and for an etching time. For example, the etching temperature is about 20° C., about 22° C., about 25° C., about 30° C., about 35° C., about 40° C., about 45° C., or about 50° C., or any ranges defined by any combination of the stated values. A lower etching temperature can help to maintain the integrity of the mask 1915 during the etching, which can enable an increased etching time and/or improved cavity shape as described herein. Additionally, or alternatively, the etching time can be about 10 minutes, about 15 minutes, about 20 minutes, about 25 minutes, about 30 minutes, about 35 minutes, about 40 minutes, about 45 minutes, about 50 minutes, about 55 minutes, about 60 minutes, about 65 minutes, about 70 minutes, about 75 minutes, about 80 minutes, about 85 minutes, or about 90 minutes, or any ranges defined by any combination of the stated values. A relatively long etching time can enable substantially straight sidewalls of the cavities or wells 1925 as described herein.

In some embodiments, the upper glass cladding layer 1905 and/or the lower glass cladding layer 1907 etch at least 1.5 times faster, at least 2 times faster, at least 5 times faster, at least 10 times faster, at least 20 times faster, or at least 100 times faster than the glass central core 110. Additionally, or alternatively, a ratio of the etch rate of the upper glass cladding layer 1905 and/or the lower glass cladding layer 1907 to the etch rate of the glass central core 1910 is about 5, about 10, about 15, about 20, about 25, about 30, about 35, about 40, about 45, about 50, about 55, about 60, about 65, about 70, about 75, about 80, about 85, about 90, about 95, about 100, or any ranges defined by any combination of the stated values.

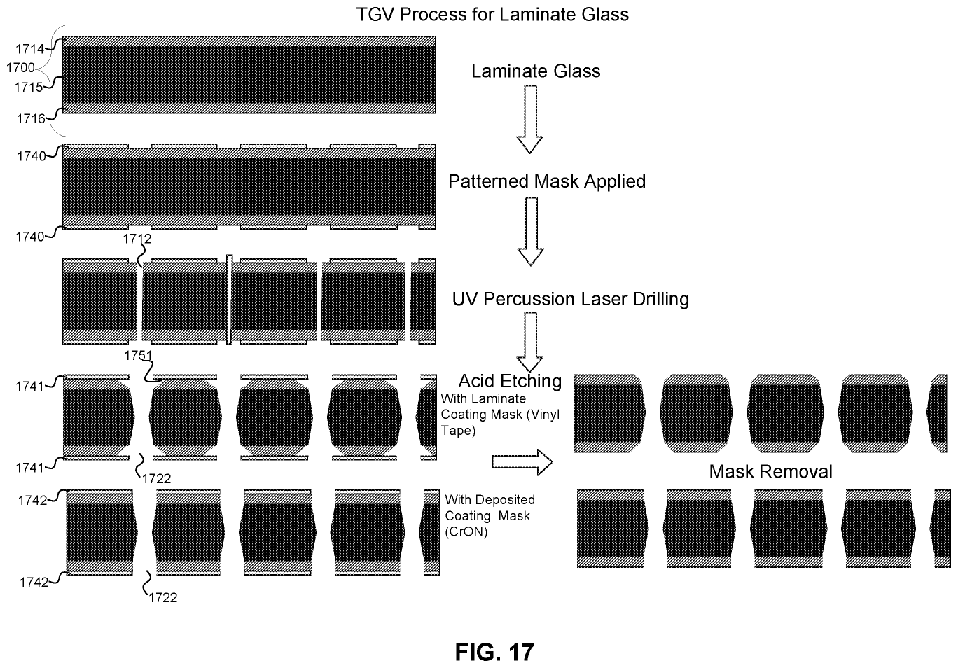

This invention takes advantage of the differing chemical compositions between the core material and the cladding material. In one instance the cladding acts as a built in masking/protective layer for the interior core. In another instance (FIG. 17) the cladding can be selectively etched away leaving defined pockets around or near a TGV. Also, because this clad is part of the glass structure and does not need to be removed after etching, it allows the glass surface to be more resistant to chemical attack from manufacturing processes and humidity attack from the environment.

Specific advantages for making TGV for a laminate glass containing fast-etching core and slow-etching clad include:

1. A durable skin layer allows the glass surface to be more resistant to chemical and mechanical attack during manufacturing processes and improves product yield. In addition, a durable skin layer can extend the resulting product lifetime by preventing it from being attacked by humidity and the chemicals from manufacturing processes.

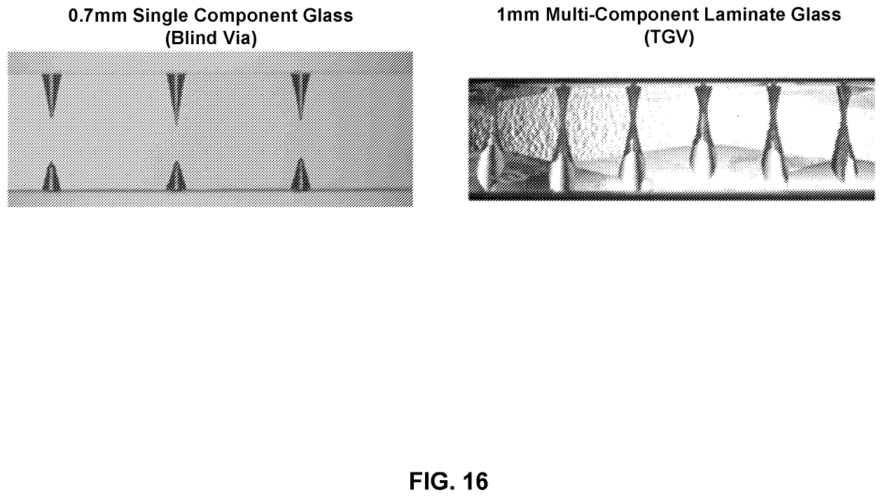

2. A fast-etching core layer allows TGV to be made much faster and or with less thickness removal in a laminate glass than a single composition glass. Current lamanent glass can achieve a core-to-clad thickness ratio of 9:1. Given we use Iris-like glass composition as the clad and Odin-like glass composition as the core, the etch rate of Iris is ˜70 times higher than Odin glass. This could allow a TGV to form in laminate glass ˜70× faster than in a similar thickness single composition glass. (See FIG. 16)

3. A high aspect ratio can be achieved using a laminate glass because the skin layer is more durable to chemical attack.

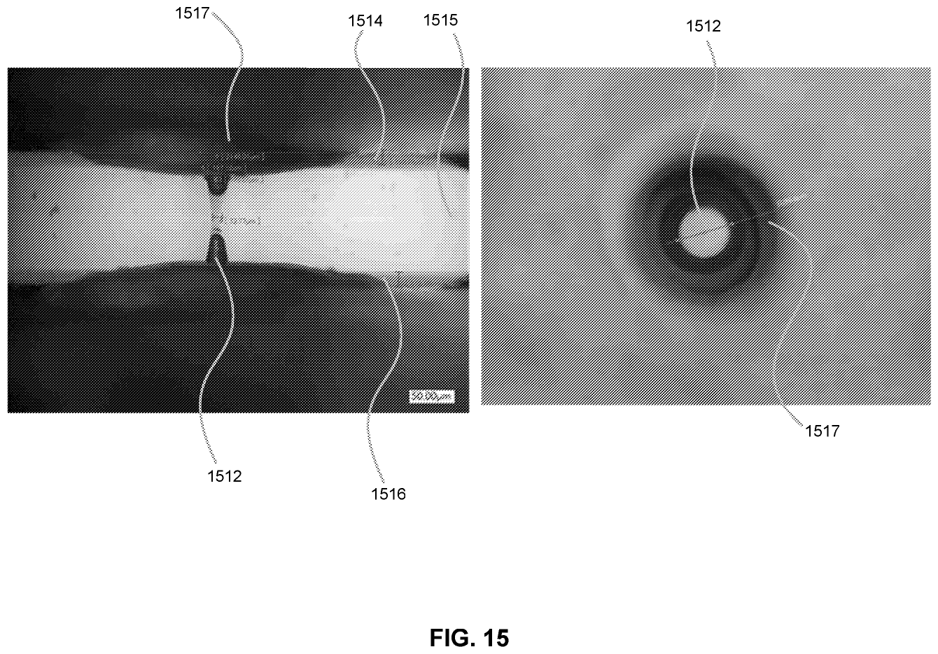

Alternately, FIG. 15 shows a TGV prepared in a laminate glass containing fast-etching clad 1514 and 1516 and slow-etching core 1515 has the advantage of functional wells 1517 can be formed near or on top of TGV 1512 by means of using an appropriate etchant to stop at the core layer 1515 of the laminate glass.

### Experimental

Sample 1 was prepared using laminated glass with a 600 μm core having the composition of Example 1, and 50 μm clad layers with the composition of Example 11 on both sides. The structure was similar to that of FIG. 10, where second layer 1015 is the 600 μm core having the composition of Example 1, and first layer 1014 and third layer 1016 are the 50 μm clad layers with the composition of Example 11.

Sample 1 was drilled using a laser technique described in previous Corning patent publications: US 2013-0247615, “Methods of Forming High-Density Arrays of Holes in Glass”, filed Nov. 30, 2011 and US 2014-0147623, “Sacrificial Cover Layers for Laser Drilling Substrates and Methods Thereof”, filed Nov. 27, 2013, which are incorporated by reference in their entireties. In the laser drilling technique used, a pulsed ultra-violet (UV) laser is focused to an approximately 6 um diameter (1/e²) spot on the surface of a sample. The laser is a frequency tripled neodymium doped yttrium orthovanadate (Nd:YVO₄) laser with a wavelength of about 355 nm. The pulse width is about 30 nsec. The average removal rate of material from the substrate was about 0.5 μm to 2 μm per pulse. So, the depth an individual drilled hole is controllable by the number of laser pulses applied. The repetition rate of the pulse train during the process is between 1 kHz and 150 kHz, with 1 kHz to 30 kHz being the most commonly used. The pilot holes formed with this method typically have a 12-16 um entry (top) diameter and a 4-8 um exit (bottom) diameter.

This laser drilling technique was used on Sample 1 with 1100 pulses at 5K repetition rate. Sample 1 was then etched in a solution containing 3M of HF and 2.4M HNO₃, with an etching time targeting a top diameter of 28 μm.

FIG. 11 shows top view and 3D view optical microscopy images of the entry and exit of an as-formed via in laminated glass.

FIG. 12 shows 3D and cross sectional views of fluorescent confocal microscopy images of the as-formed via in laminated glass. It can be seen from FIG. 12 that via photographed and labeled in Sample 1 has a via length of 700 μm, a maximum diameter of 48 μm, a minimum diameter of 20 μm, a top opening diameter of 28 μm, a bottom opening diameter of 22 μm, an aspect ratio of 14.6 (700 μm/48 μm), and a minimum diameter that is 42% of the maximum diameter (20 μm/48 μm).

FIG. 11 and FIG. 12 show how a laminate substrate structure can be used to control hole shape. In the absence of a laminate structure, for example if the whole substrate had the core composition, the hole would have continued to widen toward the surfaces, leading to a smaller aspect ratio and a lower percentage for minimum diameter/maximum diameter (i.e., a more “pinched” hole, which is a less cylindrical hole. For applications where a large aspect ratio and more cylindrical holes are desirable, Sample 1, and other samples made with similar structures and techniques, provides a solution.

### Example 18. Making TGV for a Laminate Glass Containing Fast-Etching Clad and Slow-Etching Core (Table 2)

Laminate glass has advantages of making precise glass structure compared to single glass compositions. Laminate glasses can be potentially used in microelectronics industry for electronics packaging given an etching stop layer can be developed at core-clad interface. Fabrication of TGV on these laminated glasses enables connections between the silicon chips mounted in the glass structures. However, since the exterior cladding glass is less durable than the interior core glass (E1>E2), a physical masking on the surface can be employed. As shown in FIG. 17 the physical masking 1740 can be an acid resistant laminate coating 1741 or an acid resistant deposited coating 1742. Examples of laminate coatings include a film or tape. Examples of deposited coatings include chromium oxi-nitride (CrON), tantalum, nickel (alloys) and silicone. In an embodiment, vinyl tape was used as a physical mask 1740 to protect the cladding layer 1714 and 1716. The laminate coating 1741 (i.e., vinyl tape) was patterned with 1 mm holes and aligned on either side of the glass substrate 1700. Then a UV percussion laser was used to drill pilot holes 1712 in the non-masked areas using the following parameters: 3000 pulses at 240 uJ per pulse and a repetition rate of 5 kHz. The pilot holes 1712 are tapered, inherent to the laser process, and have a 12 um and 7 um top and bottom diameter, respectively. For metallization to be possible, these pilot holes 1712 were widened through acid etching. The laser drilled samples were etched in a static bath of 2.9 M hydrofluoric acid and a 0.1 vol % polyelectrolyte fluorosurfactant additive held at 10 degrees Celsius for 9 to 10 hours. The resulting TGV 1722 has top diameter of 204 um, bottom diameter of 190 um, and waist diameter of about 80 um. There is a ˜2.5 mm diameter/200 um deep crater or well 1751 around the TGV where etchant undercut the vinyl tape and etched away the cladding material. This undercut region or well 1751 can be controlled to some degree by using a deposited coating 1742 such as chromium oxi-nitride with a controlled diameter. Undercutting for deposited coating masks should be minimal. See process flow in FIG. 17.

### Example 19. Making TGV for a Laminate Glass Containing Slow-Etching Clad and Fast-Etching Core (Table 3)

In the case of a laminate glass where the exterior cladding layer is more durable than the core (E1<E2), the cladding itself can act as a surface masking layer allowing acid to penetrate and create a TGV through the central thickness of the fast etching core material. In this case, a picosecond pulse laser using Bessel beam optics, to form a focal line, is used to create a damage track through the thickness of the glass. This damage track is preferentially etched using the same 2.9M HF 0.1 vol % polyelectrolyte surfactant solution to form a TGV.

FIG. 16 displays a TGV having a smaller top diameter in the cladding layer that expands once the faster etching core layer is reached. This is due to both the clad/core etch rate ratio below 1, in this case, 0.38, and a lower absolute etch rate for both compositions. If the same glass composition pairings were to be used in a laminate glass formed to which the core layer is thinner than the cladding, then a cylindrical via can be formed. To preserve the cladding of the laminate glass the glass was etched for 142 minutes at an etch rate of ˜0.7 um/min to remove 100 um from the surface, which produced a through hole. A single component of similar composition of glass was etched by ˜250 um at an etch rate of ˜1.34 um/min for 190 minutes and was unable to connect the damage tracks at that time. The laminate type glass saved approximately 50 minutes of process time and created a TGV by removing at least 150 um less material.

### CONCLUSION

Those skilled in the relevant art will recognize and appreciate that many changes can be made to the various embodiments described herein, while still obtaining the beneficial results. It will also be apparent that some of the desired benefits of the present embodiments can be obtained by selecting some of the features without utilizing other features. Accordingly, those who work in the art will recognize that many modifications and adaptations are possible and can even be desirable in certain circumstances and are a part of the present disclosure. Therefore, it is to be understood that this disclosure is not limited to the specific compositions, articles, devices, and methods disclosed unless otherwise specified. It is also to be understood that the terminology used herein is for the purpose of describing particular embodiments only and is not intended to be limiting. Features shown in the drawing are illustrative of selected embodiments of the present description and are not necessarily depicted in proper scale. These drawing features are exemplary, and are not intended to be limiting.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or description that the steps are to be limited to a specific order, it is no way intended that any particular order be inferred.

Unless otherwise expressly stated, percentages of glass components described herein are in mol % on an oxide basis.

It will be apparent to those skilled in the art that various modifications and variations can be made without departing from the spirit or scope of the illustrated embodiments. Since modifications, combinations, sub-combinations and variations of the disclosed embodiments that incorporate the spirit and substance of the illustrated embodiments may occur to persons skilled in the art, the description should be construed to include everything within the scope of the appended claims and their equivalents.

1. A method, comprising:
forming a pilot hole or damage track through a laminate glass structure using a laser, the laminate glass structure comprising a first layer and a second layer adjacent to the first layer;
wherein:
the first layer is formed from a first glass composition;
the second layer is formed from a second glass composition different from the first glass composition; and
after forming the pilot hole, exposing the laminate glass structure to etching conditions that etch the first glass composition at a first etching rate and the second glass composition at a second etching rate, wherein the first etch rate is different from the second etch rate, to form an etched hole.

2. The method of claim 1, wherein:
the glass laminate structure further comprises a third layer adjacent to the second layer opposite the first layer;
the third layer is formed from a third glass composition different from the second glass composition;
the third glass composition has a third etch rate when exposed to the etching conditions; and
the third etch rate is different from the second etch rate.

3. The method of claim 2, wherein the third glass composition is the same as the first glass composition, and the first etch rate is the same as the third etch rate.

4. The method of claim 2, wherein the third glass composition is different from the first glass composition, and the third etch rate is different from the first etch rate.

5. The method of claim 2, wherein:
the glass laminate structure further comprises a fourth layer adjacent to the third layer opposite the second layer;
the fourth layer is formed from a fourth glass composition different from the third glass composition;
the fourth glass composition has a fourth etch rate when exposed to the etching conditions; and
the fourth etch rate is different from the third etch rate.

6. The method of claim 1, wherein the etched hole has a first lateral dimension in the first layer and a second lateral dimension in the second layer, and wherein the first lateral dimension is different from the second lateral dimension.

7. The method of claim 6, wherein:
exposing the laminate glass structure to the etching conditions forms the etched hole which further has a third lateral dimension in the third layer, wherein the third lateral dimension is different from the second lateral dimension.

8. (canceled)

9. (canceled)

10. The method of claim 7, wherein exposing the laminate glass structure to the etching conditions forms the etched hole which further has a fourth lateral dimension in the fourth layer, wherein the fourth lateral dimension is different from the third lateral dimension.

11. The method of claim 1, wherein:
(i) the difference between the first etch rate and the second etch rate is at least 5% or more of the first etch rate; or (ii) wherein the first etch rate is greater than the second etch rate; or (iii) the first etch rate is less than the second etch rate.

12. (canceled)

13. (canceled)

14. (canceled)

15. (canceled)

16. (canceled)

17. The method of claim 2, wherein the etched hole has a morphology comprising a cylindrical shape or a shape where the lateral dimension of the first and third layer are smaller than the lateral dimension of the second layer.

18. The method of claim 2, wherein:
the first layer has an outer surface and the third layer has an outer surface; and
the first etch rate is less than the second etch rate.

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. A device, comprising:
a laminate glass structure comprising:
a first layer;
a second layer adjacent to the first layer;
a third layer adjacent to the second layer opposite the first layer;
wherein:
the first layer is formed from a first glass composition;
the second layer is formed from a second glass composition different from the first glass composition;
the third layer is formed from the first glass composition; and
a hole through the laminate glass structure has a first lateral dimension in the first layer, a second lateral dimension in the second layer, and a third lateral dimension in the third layer.

38. The device of claim 37, wherein the first lateral dimension is at least 5% or more smaller than the second lateral dimension, and the third lateral dimension is at least 5% or more smaller than the second lateral dimension.

39. The device of claim 37, wherein the second lateral dimension is at least 5% or more greater of the first lateral dimension and the second lateral dimension is at least 5% or more greater of the third lateral dimension.

40. The device of claim 38, wherein the hole has a morphology comprising a shape where the lateral dimension of the first and third layer are smaller than the lateral dimension of the second layer.

41. The device of claim 37, wherein: (i) the first lateral dimension is at least 5% or more greater than the second lateral dimension, and the third lateral dimension is at least 5% or more greater than the second lateral dimension; or (ii) the second lateral dimension is at least 5% or more smaller of the first lateral dimension and the second lateral dimension is at least 5% or more smaller of the third lateral dimension.

42. (canceled)

43. The device of claim 41, wherein the hole has a morphology comprising an hourglass shape.

44. The device of claim 37, wherein: (i) the first lateral dimension is about equal to the second lateral dimension, and the third lateral dimension is about equal to the second lateral dimension; or (ii) the second lateral dimension is about equal to the first lateral dimension and the second lateral dimension is about equal to the third lateral dimension.

45. (canceled)

46. The device of claim 44 wherein the hole has a morphology comprising a cylindrical shape.

47. The device of claim 37, wherein the hole is an etched hole.

48. The device of claim 37, wherein the hole is filled with a conductive material.

49. The device of claim 37, wherein at least one layer in the laminate glass structure is formed from a glass composition that is not photo-machinable.

50. The device of claim 37, wherein the first glass composition, and the second glass composition are not photo-machinable.
